(19) United States
(12) Patent Application Publication
(10) Pub. No.: US 2018/0074123 A1
(43) Pub. Date: Mar. 15, 2018

(54) System Test Mode For Electricity Meter In A Metering Network

(71) Applicant: Honeywell International Inc., Morris Plains, NJ (US)

(72) Inventors: Vlad Pambucol, Raleigh, NC (US); Konstantin Lobastov, Raleigh, NC (US); Peter Richard Rogers, Raleigh, NC (US)

(21) Appl. No.: 15/266,604

(22) Filed: Sep. 15, 2016

(51) Int. Cl. G01R 31/317

(52) U.S. Cl. CPC G01R 31/31701; G01R 31/31718; G01R 31/31707

(57) ABSTRACT

A system and method are provided for testing the ability of a meter to issue a notification to a utility head-end. The method comprises: entering the meter into a system test mode, wherein in system test mode the meter records actual data, actual events, and actual errors in an actual table in a memory, and the meter receives commands to induce simulated events and errors; receiving a command to induce an event or error in the meter; recording, in a test table in the memory of the meter, information indicative of the occurrence of the induced event or error; and transmitting to the utility head-end, while the meter remains in the system test mode, the information stored in the test table.

### TECHNICAL FIELD

The present invention relates to a metering system and methods, and more particularly, to systems and methods for testing metering devices.

### BACKGROUND

Meters in a metering network have various error and warning status indications that a utility is required to receive and report. To verify whether the error or warning indication is being correctly reported to the utility, end-to-end meter testing is typically used. For example, error or warning conditions are induced in the meter, which then sends the error or warning condition to a head-end system of the utility so the condition can be verified.

The foregoing background discussion is intended solely to aid the reader. It is not intended to limit the innovations described herein. Thus, the foregoing discussion should not be taken to indicate that any particular element of a prior system is unsuitable for use with the innovations described herein, nor is it intended to indicate that any element is essential in implementing the innovations described herein. The implementations and application of the innovations described herein are defined by the appended claims.

### SUMMARY

Current systems designed for meter testing include a mesh network of meters located on a test panel that are connected to a meter gateway. The meter gateway collects and aggregates test data received from the meters, and reports the test data to a system test computer. For error and warning condition testing, one or more of the meters on the test panel need to generate and report the error/warning condition. Many of the error and warning conditions are difficult or nearly impossible to induce requiring each meter to be physically accessed for the condition to be generated. For example, to test whether a memory device of the meter has failed would require an actual failure of that memory device in order to verify that the head-end system of the utility correctly receives and reports the error. In many cases, the meter would have to be at least partially disassembled to access the components that need testing. Thus, a system for inducing errors and warning conditions would greatly facilitate end-to-end meter testing.

Disclosed herein is an improved metering system for testing a plurality of meters and to more effectively test new features, system load, errors, and warnings, or still other meter operation events.

An aspect of the present disclosure provides a method for testing the ability of a meter to issue a notification to a utility head-end. In an aspect, the method comprises entering the meter into a system test mode, wherein in system test mode the meter records actual data, actual events, and actual errors in an actual table in a memory, and the meter receives commands to induce simulated events and errors; receiving a command to induce an event or error in the meter; recording, in a test table in the memory of the meter, information indicative of the occurrence of the induced event or error; and transmitting to the utility head-end, while the meter remains in the system test mode, the information stored in the test table.

Another aspect of the present disclosure provides a method for testing each of a plurality of meters in a metering system. In an aspect, the method comprises receiving a first command by a first meter of the plurality of meters, wherein the first command is configured to invoke a first test function stored in a memory of the meter and enter the first meter into a system test mode; receiving a second command by the first meter, wherein the second command is configured to invoke a second test function stored in the memory of the first meter and induce a test event; recording information indicative of the occurrence of the test event in a test table in the memory of the first meter; and reporting the information stored in the test table, while the meter remains in the system test mode, to a head-end system.

Another aspect of the present disclosure provides a metering system for testing a plurality of meters. Each of the plurality of meters comprises a memory and a processor. The memory includes a first table and a second table. The processor is configured to receive a first command that invokes a first test function stored in the memory, wherein the first test function enters the meter into a system test mode; execute the first test function; receive a second command that invokes a second test function stored in the memory, wherein the second test function induces a test event; execute the second test function; record the test event in the first table; and record actual meter events in the second table.

This summary is provided to introduce a selection of concepts in a simplified form that are further described below in the Description of the Invention section. This Summary is not intended to identify key features or essential features of the claimed subject matter, nor is it intended to be used to limit the scope of the claimed subject matter. Furthermore, the claimed subject matter is not constrained to limitations that solve any or all disadvantages noted in any part of this disclosure.

### BRIEF DESCRIPTION OF THE DRAWINGS

A more detailed understanding may be had from the following description, given by way of example in conjunction with the accompanying drawings, wherein:

FIG. 1 illustrates a metering system in which the systems, methods, and apparatus disclosed herein may be embodied.

FIGS. 2A and 2B illustrate schematics of a meter in the metering system of FIG. 1, according to an aspect of the disclosure.

FIG. 3 illustrates a table that includes a list of errors and warnings that could be induced in the metering system of FIG. 1, according to an aspect of the disclosure.

FIG. 4 illustrates a flow diagram for testing a metering system, according to an aspect of the disclosure.

FIG. 5 illustrates a computing environment in which the systems, methods, and apparatus disclosed herein may be embodied.

### DESCRIPTION OF THE INVENTION

The disclosure relates generally to metering systems and methods for monitoring consumption of a commodity, such as electricity. It is understood that the systems and methods described herein may be implemented in systems that monitor consumption of other commodities, such as, for example, water or gas. In one embodiment, the metering system includes a plurality of meters communicatively connected to a head-end system. The connection could be a physical connection such as a cable between the meter and the head-end system, a wireless RF connection, or other means. The ability of a plurality of meters to issue notifications to a head-end system may be tested by setting at least one of the plurality of meters to a system test mode. During system test mode, the head-end system may induce various events, errors, and/or warnings in the plurality of meters. The induced events, errors, and/or warnings may be recorded in tables and stored in a meter memory. The tables may be accesses and/or sent to the head-end system and verified. After testing is complete, the plurality of meters may exit system test mode.

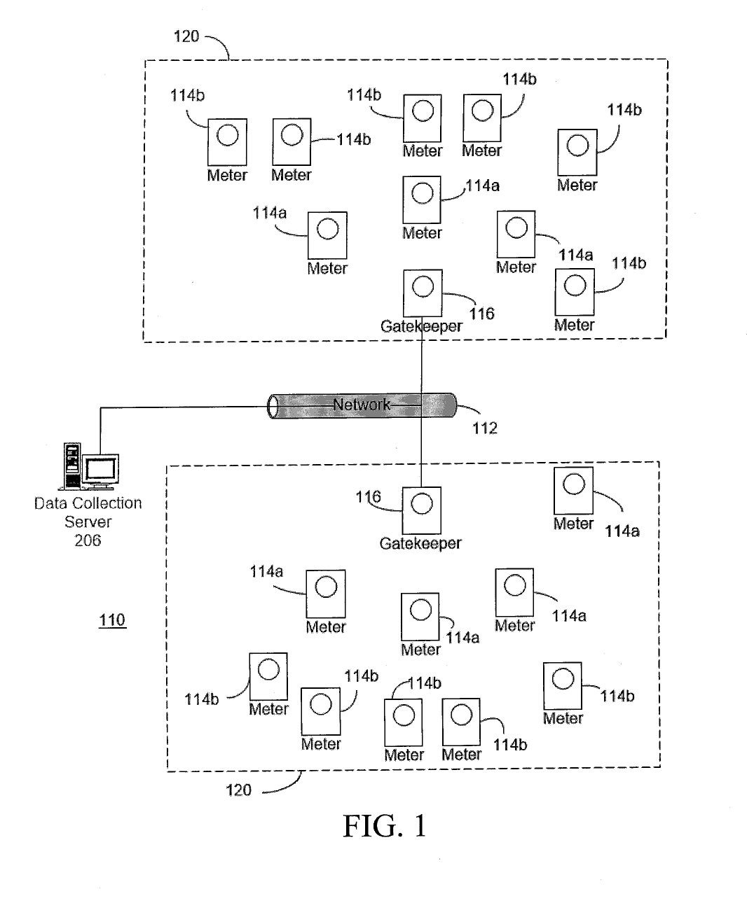

FIG. 1 provides a diagram of an embodiment of a metering system 110 in which the methods, systems, and apparatus disclosed herein may be employed. System 110 comprises a plurality of meters 114, which are operable to sense and record consumption or usage of a service or commodity such as, for example, electricity, water, or gas. Meters 114 may be located at customer premises such as, for example, a home or place of business. Meters 114 comprise circuitry for measuring the consumption of the service or commodity being consumed at their respective locations and for generating data reflecting the consumption, as well as other data related thereto. Meters 114 may also comprise circuitry for wirelessly transmitting data generated by the meter to a remote location. Meters 114 may further comprise circuitry for receiving data, commands or instructions wirelessly as well. Meters that are operable to both receive and transmit data may be referred to as “bi-directional” or “two-way” meters (or nodes), while meters that are only capable of transmitting data may be referred to as “transmit-only” or “one-way” meters. In bi-directional meters, the circuitry for transmitting and receiving may comprise a transceiver.

System 110 further comprises gatekeepers 116. In some embodiments, the gatekeepers 116 may also be referred to as a “collectors” or “routers.” In one embodiment, the gatekeepers 116 are also meters operable to detect and record usage of a service or commodity such as, for example, electricity, water, or gas. In addition, gatekeepers 116 are operable to send data to and receive data from meters 114. Thus, like the meters 114, the gatekeepers 116 may comprise both circuitry for measuring the consumption of a service or commodity and for generating data reflecting the consumption and circuitry for transmitting and receiving data. In one embodiment, gatekeeper 116 and meters 114 communicate with and amongst one another using a frequency hopping communications technique, such as, for example, a frequency hopping spread spectrum (FHSS) technique or direct sequence spread spectrum (DSSS).

In one embodiment, the gatekeepers 116 and the meters 114 with which it communicates define a subnet or local area network (LAN) 120. The LAN 120 may define a controlled, wireless mesh network with the gatekeepers 116 of that LAN effectively controlling the mesh network.

As used herein, the gatekeepers 116 and the meters 114 may be referred to as “nodes” in the subnet/LAN 120. In the subnet/LAN 120, the meters 114 transmit data related to consumption of the commodity being metered at the meter's location. The gatekeepers 116 receive the data transmitted by each meter 114, effectively “collecting” it, and then periodically transmit the data from all of the meters in the subnet/LAN 120 to a data collection server 206 (e.g. utility head-end system). The data collection server 206 stores the data for analysis and preparation of bills, for example. The data collection server 206 may be a specially programmed general purpose computing system and may communicate with gatekeepers 116 via a network 112. The network 112 may comprise any form of network, including a wireless network or a fixed-wire network, such as a local area network (LAN), a wide area network (WAN), the Internet, an intranet, a telephone network, such as the public switched telephone network (PSTN), a Frequency Hopping Spread Spectrum (FHSS) radio network, a mesh network, a Wi-Fi (802.11) network, a Wi-Max (802.16) network, a land line (POTS) network, a TCP/IP network, a W-WAN, a GPRS network, a CDMA network, a Fiber network, or any combination of the above.

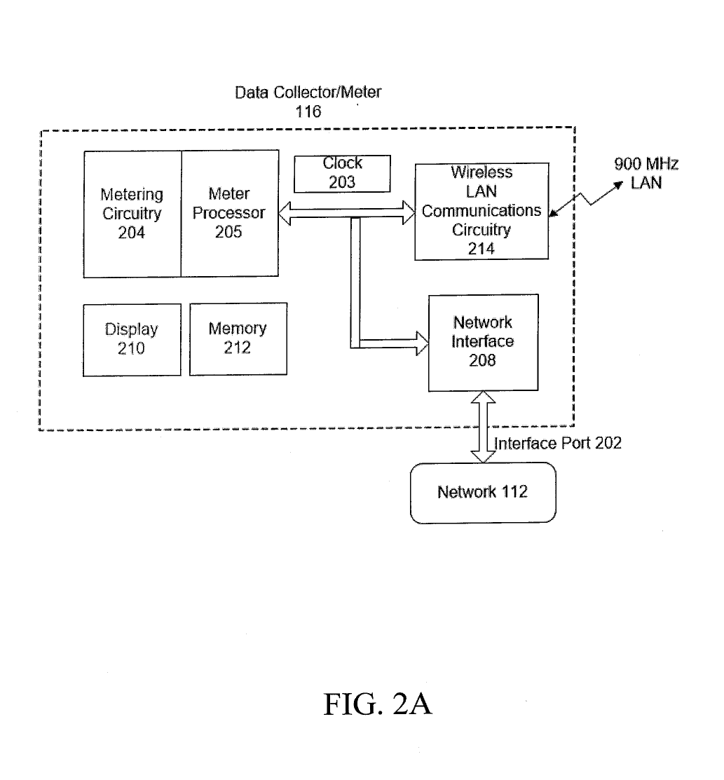

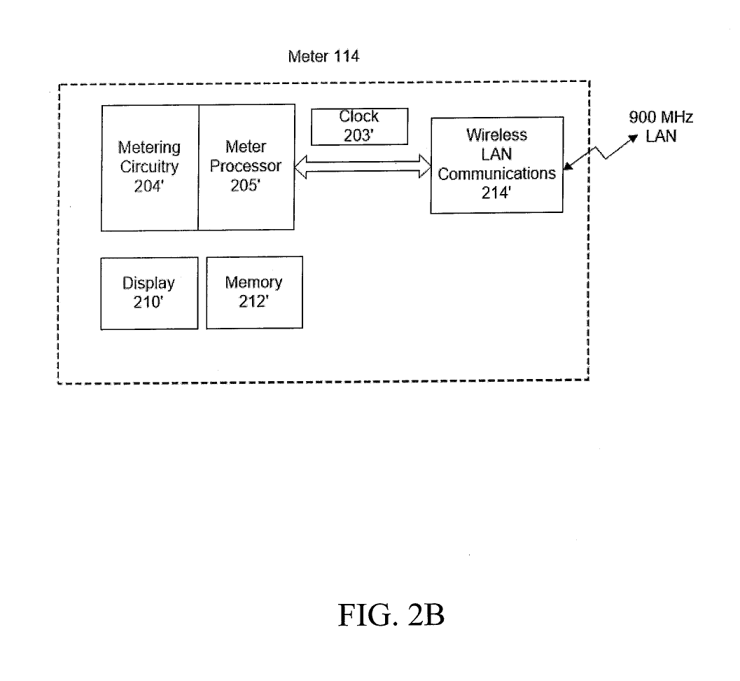

FIG. 2A is a block diagram illustrating further details of one embodiment of a gatekeeper 116. Although certain components are designated and discussed with reference to FIG. 2A, it should be appreciated that the invention is not limited to such components. In fact, various other components typically found in an electronic meter may be a part of gatekeeper 116, but have not been shown in FIG. 2A for the purposes of clarity and brevity. Also, the invention may use other components to accomplish the operation of gatekeeper 116. The components that are shown and the functionality described for gatekeeper 116 are provided as examples, and are not meant to be exclusive of other components or other functionality.

As shown in FIG. 2A, gatekeeper 116 may comprise metering circuitry 204 that performs measurement of consumption of a service or commodity and a processor 205 that controls the overall operation of the metering functions of the gatekeeper 116. The gatekeeper 116 may further comprise a display 210 for displaying information such as measured quantities and meter status and a memory 212 for storing data. The gatekeeper 116 further comprises wireless LAN communications circuitry 214 for communicating wirelessly with the meters 114 in a subnet/LAN and a network interface 208 for communication over the network 112. The communications circuitry 214 may be a two-way communications interface to the data collection server 206 and may comprise any suitable communications interface technology, such as a radio frequency (RF) transceiver, or an interface to the telephone lines or power lines at a utility location, etc. The communications circuitry 214 may communicate with the data collection server 206 over private or public networks.

As further shown, the gatekeeper 116 includes a clock circuit 203. The clock circuit 203 for the gatekeeper 116 may run off an internal 12 MHz crystal and may be adjusted from the central station on a daily basis (or more often). During outages, the clock circuit 203 may keep using a 32 kHz crystal. In an alternative embodiment, the gatekeeper 116 may use a 60 Hz line frequency for additional timing accuracy adjustments.

FIG. 2B is a block diagram of an exemplary embodiment of a meter 114 that may operate in the system 110 of FIG. 1. As shown, the meter 114 comprises metering circuitry 204′ for measuring the amount of a service or commodity that is consumed, a processor 205′ that controls the overall functions of the meter, a display 210′ for displaying meter data and status information, and a memory 212′ for storing data and program instructions. The meter 114 further comprises wireless communications circuitry 214′ for transmitting and receiving data, such as error and warning conditions, to/from other meters 114 or the gatekeeper 116. The wireless communications circuitry 214′ may be similar to or identical to the wireless communication circuitry 214 in the gatekeeper 116 of FIG. 2A. The meter 114 also comprises a clock circuit 203′ like the gatekeeper 116. The clock circuit 203′ may be similar or identical to the clock circuit 203 used in the gatekeeper 116.

The gatekeepers 116 may be responsible for managing, processing and routing data communicated between the gatekeeper 116 and network 112 and between the gatekeeper 116 and meters 114. The gatekeepers 116 may continually or intermittently receive current data from meters 114 and store the data in memory 212 or a database (not shown) in gatekeeper 116. Such current data may include but is not limited to the total kWh usage, the Time-Of-Use (TOU) kWh usage, peak kW demand, other energy consumption measurements, error and warning conditions, or other status information. The gatekeepers 116 also may receive and store previous billing and previous season data from meters 114 and store the data in memory 212 or the database in gatekeeper 116. The database may be implemented as one or more tables of data within the gatekeeper 116.

In an embodiment, the metering system 110 may be an Advanced Metering Infrastructure (AMI) system which uses the ANSI C12.22 protocol for interfacing with the network 112. It should be appreciated that other protocols may be used for the methods and systems for data communications defined herein, for example, ANSI C12.18, and ANSI C12.21. The protocol makes provisions for encrypting data to enable secure communications, including confidentiality and data integrity, for the purpose of interoperability between metering devices and the network.

In an embodiment, the LAN/subnet 120 formed by the gatekeepers 116 and the plurality of meters 114 that communicate with it may operate to form a wireless mesh network that implements FHSS techniques in the 900 MHz ISM band. It should be appreciated that the system and method disclosed herein may comply with Federal Communications Commission (FCC) part 15.247 while providing mechanisms for devices (e.g., meters 114 and gatekeepers 116) to join, register, synchronize, and find neighbors within a LAN/subnet.

The memory 212 may include random access memory (RAM), read-only memory (ROM), non-volatile memory, such as electrically erasable programmable ROM (EEPROM) or flash memory, or combinations thereof. Each meter 114 may maintain in memory 212 different types of time-stamped logs to record various types of event information. The information may include event logs, power quality monitor (PQM) logs, and history logs. The event logs may include, for example, power fails, time changes, etc. The PQM logs may include, for example, over-voltage or over-current events. The history logs may include, for example, table write command or stored procedure execution occurrences.

In an aspect, each meter 114 may operate in a normal mode or a system test mode. In both modes, the meter 114 monitors metering operations and records billing data, events, errors, warnings, and alarms to memory 212. Each mode may be implemented in the metrology firmware, and may be invoked by calling a manufacturing function by communicating with the meter 114 (either optically or over the network 112).

During normal mode, the meter 114 may record the actual billing data, actual events, and actual errors, warnings, and alarms in an actual table stored in memory 212. The actual table stores actual metering operation data, as opposed to induced metering operation data. Data may be requested by the data collection server 206 from the actual table. In an aspect, the actual table may be stored in a non-volatile memory.

Each meter 114 may be set to the system test mode from the normal mode by transmitting a command to the meter 114 that sets a system test mode bit in a meter status table stored in memory 212. The system test mode bit may indicate whether the system test mode is active. An access control table, which may be stored in memory 212, may control access to certain procedures or functions stored in memory 212. For example, a command may be sent to set the system test mode bit, which is then stored in the meter status table. If the metering system 110 uses ANSI C12.19 table structure, the access control table ST-44, which is defined in the ANSI C12.19 structure, may list a set of procedures that are accessible only when the system test mode bit is set. A command to execute a procedure may be sent to the meter 114, and the access control table ST-44 may indicate whether this procedure is executable during system test mode. If the access control table ST-44 indicates the procedure is executable during system test mode, then the procedure is executed. After testing is complete, a command may be transmitted to the meter 114 to unset the system test mode bit and the meter may return to normal mode. In an aspect, the system test mode should only be allowed through a securely controlled mechanism.

During system test mode, system test tables and functions may be accessed by the data collection server 206. These test tables and functions may have a ‘system test access level required’ bit set in the access control table (i.e. ST-44). In an aspect, tables that do not have the ‘system test access level required’ bit set may not be accessed. Each of the following meter subsystems may be set: Errors and warnings, PQM log, event log, and history log. In alternative aspects, other meter subsystems or tables may be configured to also be set.

To add an event during system test mode to one of the meter subsystems or tables, a command may be transmitted to the meter 114 that calls a manufacturer procedure (i.e. ADD_EVENT_TO_LOG). For example, the manufacture's procedure may be called with a ‘LOG_TYPE_SELECTOR’ set to ‘EVENT_LOG’ and a ‘LOG_ARGUMENT’ set to ‘EVENT_ID’ (i.e. event number for the event log). If the meter 114 accepts the command based on security permissions and if the access control table indicates that the manufacturer procedure is executable during system test mode, then the meter 114 logs the ‘EVENT_ID’ event with a current meter time in the event log in a test RAM table, which is further described below. This process may also work for the PQM log and the history log.

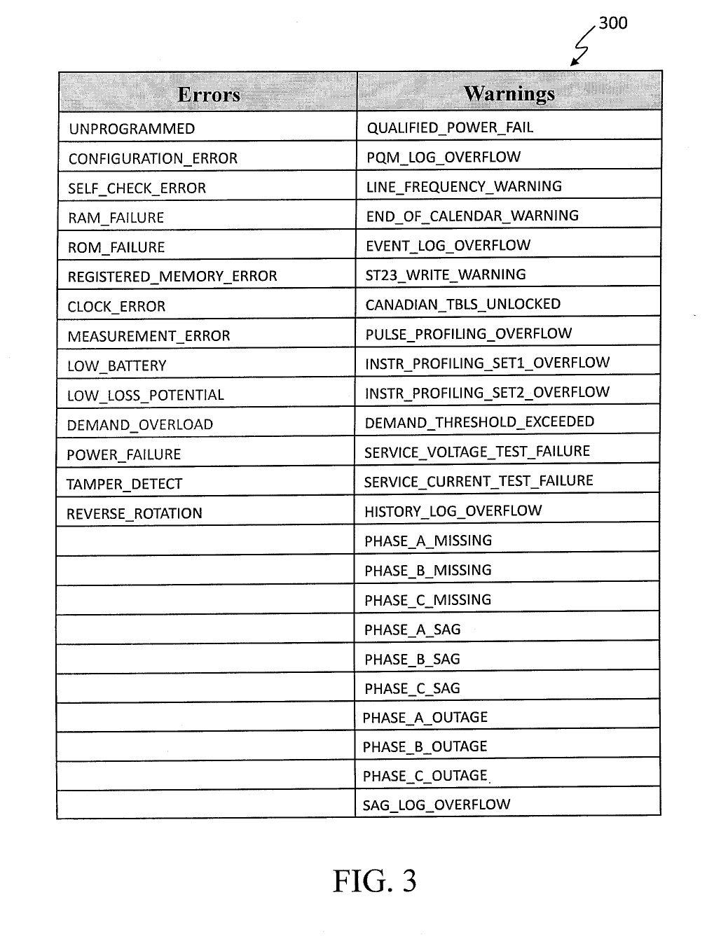

To add an error, warning, or alarm during system test mode to one of the meter subsystems or tables, a command may be transmitted to the meter 114 that calls a manufacturer's procedure (i.e. ADD_ERRORS_AND_WARNINGS). If the meter 114 accepts the command based on security permissions and if the access control table indicates that the manufacturer procedure is executable during system test mode, then the manufacturer's procedure is invoked and executed which may add any error, warning, or alarm that the meter 114 can generate to the test RAM table. FIG. 3 illustrates a Table 300 that includes a list of errors and warnings that could be added to the meter 114 in the system test mode. The list of errors and warnings is not exhaustive, and merely illustrates an exemplary set of errors and warnings that may be induced. Further, the categorization of errors and warnings is also exemplary, such that one skilled in the art may consider errors listed under the errors heading to be warnings and vice versa.

During system test mode, the meter 114 operates by recording billing data, actual events, and actual errors and alarms in the actual tables stored in memory 212. A difference between system test mode and normal mode is that during system test mode any induced events, log entries, errors and warnings may be recorded in test RAM tables stored in memory 212. The test RAM tables may only be read during system test mode. The test RAM tables may mirror the actual tables stored in memory 212, such that the test RAM tables have substantially the same structure as the actual tables and each of the attributes of the test RAM tables are consistent with each of the attributes of the actual tables. All of the events, errors, warnings, alarms, etc. that have been induced during system test mode may be reported to the data collection server 206 from the test RAM tables. The reporting may take place at predetermined time intervals, or the reporting may be based on a reply to a data request transmitted to the meter 114. Data requests and replies to and from the data collection server 206 during system test mode may be identical to the requests and replies to and from the data collection server 206 during normal mode. An exception is that the data returned to the data collection server 206 comes from the test RAM tables instead of the actual tables.

In an aspect, the meter 114 may operate in both the system test mode and the normal mode, such that the system test mode and the normal mode are done in parallel. Any induced events, errors, and warning may be saved to the test RAM tables, and any actual events, errors, and warnings may be saved to the actual tables.

The system test mode may be terminated via a manufacturer's procedure or timeout. A command may be transmitted to the meter 114 to execute a system test mode exit procedure which may unset the system test mode bit in the meter status table. The meter 114 may then discard all of the data stored in the test RAM tables and resume meter operations in normal mode.

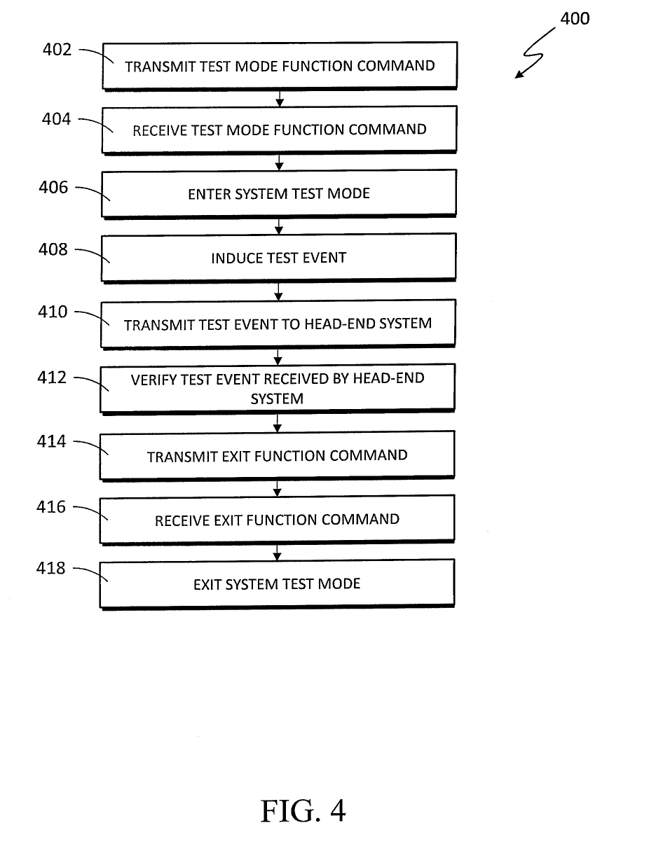

FIG. 4 illustrates a method 400 for testing meter 114. Method 400 may be performed on one or more meters 114 and/or one or more gatekeepers 116. In this example, meter 114 has been upgraded with a new feature or capability that includes a new event. Although the new feature may have been tested in a lab setting, it may not be known how the head-end system 206 will react to the new feature being deployed to meter 114. For example, if a new event is added to the meter 114, it may not be known how the already deployed meter 114 will report the new event generated by the meter 114. To test the new event and determine whether the new event will be reported properly through the meter reading system when the event occurs, the new event may be simulated by inducing the event during system test mode.

At step 402, the head-end system 206 may transmit a command to execute the system test mode function stored in the memory 212 of the meter 114. This command may be sent to a single meter 114, or may be broadcasted to a plurality of meters 114 and/or gatekeepers 116. At steps 404 and 406, the meter 114 receives the command to execute the test mode function and enters into the system test mode by setting the system test mode bit in the meter status table. The test RAM tables may be setup and initialized in preparation for recording test events. At step 408, the head-end system 206 transmits another command to invoke and execute a function stored in memory 212 that induces the new test event. If the meter 114 accepts the command based on security permissions and if the access control table indicates that the function is executable during system test mode, then the meter 114 induces the new test event by executing the function. The command to induce the new test event in the meter 114 may include a call that invokes the procedure stored within the memory 212 that simulates the new test event. The meter 114 then records the new test event in the test RAM tables. Any actual events that occur during system test mode may be stored in the actual tables. At step 410, the new test event is transmitted by the meter 114 to the head-end system 206. The transmission of the new test event may be considered a notification issued to the head-end system 206 that indicates the new test event was successfully recorded in memory 212. At step 412 the head-end system 206 verifies that the new test event has been received.

Once the system test of meter 114 is complete, at step 414, the head-end system 206 may send an exit command to the meter 112 to execute the exit system test mode function stored in memory 212. At step 416, the meter 114 receives the exit command. If the meter 114 accepts the command based on security permissions and if the access control table indicates that the exit system test mode function is executable during system test mode, the exit system test mode function is executed. At step 418, the system test mode bit stored in the meter status table may be unset and the meter 114 exits from the system test mode. Upon exiting, the test RAM tables may be cleared from memory 212. The induced event may not be recorded in the actual meter tables. However, any actual events, actual errors, actual alarms, or other actual metering activity that are detected by the meter 114 during the system test mode may be reported to the head-end system 206 upon exiting the system test mode.

Method 400 may also be used for head-end system load testing. Head-end systems 206 handle a large number of meters 114 (i.e. thousands or millions of meters) reporting events substantially simultaneously. For example, a power outage in a residential area can result in thousands of meters 114 reporting the outage to the head-end system 206. It may not be feasible to cause a massive power outage to facilitate such a large system load test. The system test mode may be used to effectively perform such a system load test by simulating the outage event using the system test mode function.

It will be appreciated that new feature testing and load testing are merely demonstrative, and more scenarios and corresponding responses may be contemplated using system test mode. Further, additional or fewer events may be incorporated into each system test mode in order to determine whether the meter 114 and the head-end system 206 are transmitting and receiving appropriate event and/or test information.

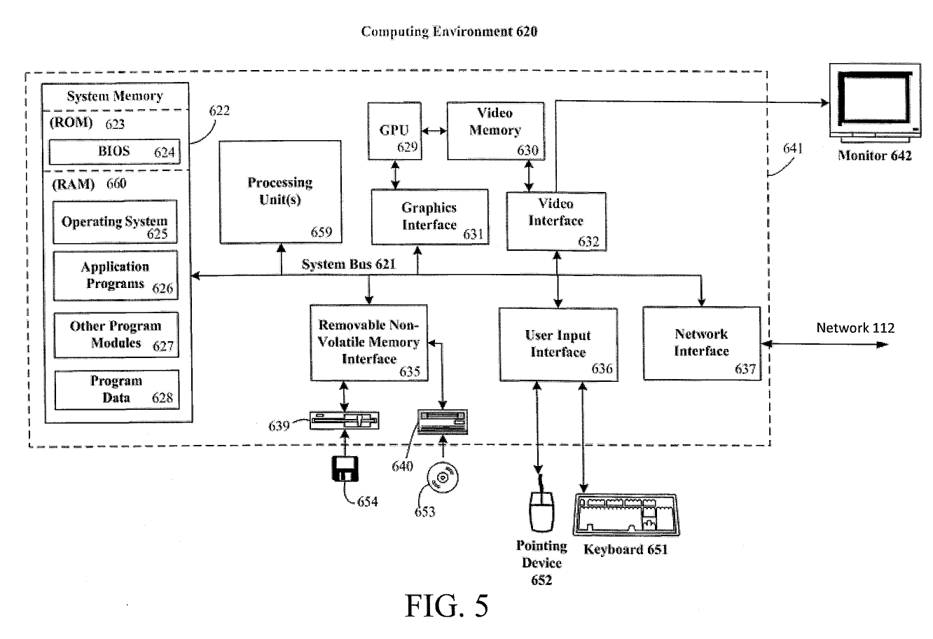

FIG. 5 is an example embodiment of a computing environment 620 of which various aspects of the metering system 110 could be implemented. For example, the computing environment 620 may be used to implement the data collection server 206, or any other aspect of the disclosed system that requires computing. The computing environment 620 is only one example of a suitable computing environment and is not intended to suggest any limitation as to the scope of use or functionality of the presently disclosed subject matter. Neither should the computing environment 620 be interpreted as having any dependency or requirement relating to any one or combination of components illustrated in FIG. 5. In some embodiments, the various depicted computing elements may include circuitry configured to instantiate specific aspects of the present disclosure. For example, the term circuitry used in the disclosure can include specialized hardware components configured to perform function(s) by firmware or switches. In other example embodiments, the term circuitry can include a general purpose processing unit, memory, etc., configured by software instructions that embody logic operable to perform function(s). In example embodiments where circuitry includes a combination of hardware and software, an implementer may write source code embodying logic and the source code can be compiled into machine readable code that can be processed by the general purpose processing unit. Since the state of the art has evolved to a point where there is little difference between hardware, software, or a combination of hardware/software, the selection of hardware versus software to effectuate specific functions is a design choice left to an implementer. More specifically, a software process can be transformed into an equivalent hardware structure, and a hardware structure can itself be transformed into an equivalent software process. Thus, the selection of a hardware implementation versus a software implementation is one of design choice and left to the implementer.

In FIG. 5, the computing environment 620 comprises a computer 641. The computer 641 comprises a processing unit(s) 659, which may comprise a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Array (FPGAs) circuits, any other type of integrated circuit (IC), a state machine, and the like. The processing unit(s) 659 may perform signal coding, data processing, power control, input/output processing, and/or any other functionality that enables the computing environment 620 to operate in accordance with its intended functionality. The computer 641 may further comprise a graphics interface, graphics processing unit (GPU), video memory 630, and video interface. These components may cooperate to display graphics and text on a video monitor, such as monitor 642. Processing unit(s) 659 and GPU 629 may receive, generate, and process data related to the methods and apparatuses disclosed herein.

In operation, processing unit(s) 659 fetches, decodes, and executes instructions, and transfers information to and from other resources via the computer's main data-transfer path, system bus 621. Such a system bus connects the components in computer 641 and defines the medium for data exchange. System bus 621 typically includes data lines for sending data, address lines for sending addresses, and control lines for sending interrupts and for operating the system bus. An example of such a system bus 621 is the PCI (Peripheral Component Interconnect) bus. A system memory 622 includes computer storage media in the form of volatile and/or nonvolatile memory such as ROM 623 and RAM 660. A basic input/output system 624 (BIOS), containing the basic routines that help to transfer information between elements within computer 641, such as during start-up, is typically stored in ROM 623. RAM 660 typically contains data, data tables, and/or program modules that are immediately accessible to and/or presently being operated on by processing unit 659. By way of example, and not limitation, FIG. 5 illustrates operating system 625, application programs 626, other program modules 627, and program data 628.

The computer 641 may also include other removable/non-removable, volatile/nonvolatile computer storage media. By way of example only, the computer 641 may include a hard disk drive (not shown) that reads from or writes to non-removable, nonvolatile magnetic media, a magnetic disk drive 639 that reads from or writes to a removable, nonvolatile magnetic disk 654, and an optical disk drive 640 that reads from or writes to a removable, nonvolatile optical disk 653 such as a CD ROM or other optical media. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM, and the like. Magnetic disk drive 639 and optical disk drive 640 are typically connected to the system bus 621 by a removable memory interface, such as interface 635. The drives and their associated computer storage media discussed above and illustrated in FIG. 5, provide storage of computer readable instructions, data structures, program modules and other data for the computer 641.

A user may enter commands and information into the computer 641 through input devices such as a keyboard 651 and pointing device 652, commonly referred to as a mouse, trackball or touch pad. Other input devices (not shown) may include a microphone, joystick, game pad, satellite dish, scanner, or the like. These and other input devices are often connected to the processing unit 659 through a user input interface 636 that is coupled to the system bus, but may be connected by other interface and bus structures, such as a parallel port, game port or a universal serial bus (USB). The computer may connect to a local area network or wide area network, such as network 112, through a network interface or adapter 637.

Thus, it is understood that any or all of the apparatuses, systems, methods and processes described herein may be embodied in the form of computer executable instructions (i.e., program code) stored on a computer-readable storage medium which instructions, when executed by a processor, such as processing unit(s) 659, cause the processor to perform and/or implement the systems, methods and processes described herein. Specifically, any of the steps, operations or functions described herein may be implemented in the form of such computer executable instructions, executing on the processor of a computing system or other computing apparatus. Computer readable storage media include both volatile and nonvolatile, removable and non-removable media implemented in any non-transitory (i.e., tangible or physical) method or technology for storage of information, but such computer readable storage media do not includes signals. Computer readable storage media include, but are not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other tangible or physical medium which can be used to store the desired information and which can be accessed by a computing system.

While the disclosure is described herein using a limited number of embodiments, these specific embodiments are for illustrative purposes and are not intended to limit the scope of the disclosure as otherwise described and claimed herein. Modification and variations from the described embodiments exist. The scope of the invention is defined by the appended claims.

What is claimed is:

1. A method for testing the ability of a meter to issue a notification to a utility head-end, the method comprising:
entering the meter into a system test mode, wherein in system test mode the meter records actual data, actual events, and actual errors in an actual table in a memory, and the meter receives commands to induce simulated events and errors;
receiving a command to induce an event or error in the meter;
recording, in a test table in the memory of the meter, information indicative of the occurrence of the induced event or error; and
transmitting to the utility head-end, while the meter remains in the system test mode, the information stored in the test table.

2. The method recited in claim 1, further comprising:
receiving, by a communications interface of the meter, a command to enter the system test mode; and
entering the system test mode in response to the command.

3. The method recited in claim 1, wherein receiving the command to induce the event or error in the meter comprises receiving a call that invokes a procedure stored within the memory of the meter that simulates the event or error.

4. The method recited claim 3, where the procedure stored within the memory is implemented in accordance with the ANSI C12.19 protocol.

5. The method recited in claim 1, wherein the test table mirrors the structure of the actual table.

6. In a metering system having a plurality of meters, a method for testing each of the plurality of meters comprising:
receiving a first command by a first meter of the plurality of meters, wherein the first command is configured to invoke a first test function stored in a memory of the meter and enter the first meter into a system test mode;
receiving a second command by the first meter, wherein the second command is configured to invoke a second test function stored in the memory of the first meter and induce a test event;
recording information indicative of the occurrence of the test event in a test table in the memory of the first meter; and
reporting the information stored in the test table, while the meter remains in the system test mode, to a head-end system.

7. The method of claim 6, further comprising:
transmitting the first command to the first meter by the head-end system.

8. The method of claim 6, further comprising:
receiving the test event by the head-end system; and
verifying that the test event was received by the head-end system.

9. The method of claim 6, further comprising:
recording actual meter events to an actual table stored in the memory of the meter; and
reporting the actual table by the first meter to the head-end system.

10. The method of claim 6, further comprising:
receiving, by the plurality of meters, the first command;
entering the plurality of meters into the system test mode;
receiving, by the plurality of meters, the second command;
recording the test event in a test table in a memory of each of the plurality of meters; and
reporting the information stored in each test table in the memory of each of the plurality of meters to the head-end system.

11. The method of claim 10, wherein each of the plurality of meters reports the information stored in each respective test table to the head-end system substantially simultaneously.

12. The method of claim 6, further comprising:
receiving a third command by the first meter, wherein the third command is configured to invoke a third test function stored in the memory of the meter, wherein the third test function is configured to exit the first meter from the system test mode; and
executing the third test function.

13. The method of claim 12, further comprising:
transmitting the third test function to the first meter by the head-end system;

14. The method of claim 12, further comprising:
clearing the test event recorded in the table from the memory of the first meter.

15. The method of claim 12, further comprising:
indicating, by an access control table, whether the second test function is executable in the system test mode.

16. The method of claim 12, wherein the test event includes at least one of (i) a memory failure, (ii) a configuration error, (iii) a clock error, (iv) a measurement error, (v) a low battery, (vi) a power failure, (vii) a tamper detection, and (viii) reverse rotation.

17. A metering system comprising:
a plurality of meters, each of the plurality of meters comprising:
a memory having a first table and a second table; and
a processor configured to:
receive a first command that invokes a first test function stored in the memory, wherein the first test function enters the meter into a system test mode,
receive a second command that invokes a second test function stored in the memory, wherein the second test function induces a test event,
record the test event in the first table, and
record actual meter events in the second table.

18. The metering system of claim 17, wherein each of the plurality of meters further comprises a transceiver configured to transmit the first table and the second table to a head-end system.

19. The metering system of claim 17, wherein the processor is further configured to receive a third command that invokes a third test function stored in the memory, wherein the third test function exits the meter from the system test mode.

20. The metering system of claim 17, wherein a control access table is stored with the memory of the meter, wherein the control access table indicates whether the second test function is executable when the meter is in the system test mode.
